(19) United States
(12) Patent Application Publication
(10) Pub. No.: US 2019/0273072 A1
(43) Pub. Date: Sep. 5, 2019

(54) Chip Scale Package Light Emitting Diode Module For Automotive Lighting Applications

(71) Applicant: AB Mikroelektronik Gesellschaft mit beschraenkter Haftung, Salzburg (AT)

(72) Inventors: Sebastian Rohm, Salzburg (AT); Wolfgang Tusler, Salzburg (AT); Martin Zippel, Grabenstätt (DE)

(21) Appl. No.: 16/268,605

(22) Filed: Feb. 6, 2019

Related U.S. Application Data
(60) Provisional application No. 62/637,685, filed on Mar. 2, 2018.

(51) Int. Cl. H01L 25/13; H01L 33/60; F21S 41/153; F21S 43/14

(52) U.S. Cl. CPC H01L 25/13; H01L 33/60; H01L 33/486; F21S 43/14; F21S 41/153

(57) ABSTRACT

LED modules for use in, for instance, automotive applications are provided. In one example implementation, the LED module can include a substrate. The LED module can include a plurality of chip-scale package LEDs. The plurality of chip-scale package LEDs can be arranged in a matrix on the substrate. Each chip-scale package LED can have a light emitting area that is about 80% or greater of a total area associated with the chip-scale package LED. Each chip-scale package LED can be separated from an adjacent chip-scale package LED by a gap. In some embodiments, a side coat material can be disposed in the gap.

### PRIORITY CLAIM

The present application claims the benefit of priority of U.S. Provisional Application Ser. No. 62/637,685, titled “Chip Scale Package Light Emitting Diode Module for Automotive Lighting Applications,” filed Mar. 2, 2018, which is incorporated herein by reference for all purposes.

### FIELD

The present disclosure relates generally to light emitting diode (LED) systems used, for instance, for providing lighting in automotive and other applications

### BACKGROUND

LEDs are being increasingly used in automotive applications, for instance, for use in vehicle headlights, rear lights, and/or as a light source for liquid crystal display (LCD) and digital micro-mirror device (DMD) headlights. A goal of external lighting of vehicles is to combine several light functions, such as low beam, high beam, daytime running light, into a single module. This has been achieved, for instance, by using several LEDs arranged in a matrix-like structure. The light emitted from the LEDs is first cumulated by one or more lenses forming a primary optic. The light can then be projected from the vehicle by a secondary optic.

DE 10 2008 013 603 A1 discloses implementing a lens array as a primary optic. Each LED has its own lens, which cumulates and diverts the light, so that a homogenous light distribution is projected from the vehicle. However, such a lens-array needs to fulfill very precise tolerances and is, therefore, complicated and expensive.

DE 10 2016 207 787 A1 discloses generating a homogenous light distribution by a multitude of small LED pixels arranged on a single LED chip. This chip can contain, for instance, up to 1024 pixels, whereby each pixel can be controlled and operated individually. However, such a chip is very complex and can be difficult to adapt to individual requirements.

US 2015/0377442 offers a high pixel approach via high-definition systems like digital micromirror devices (DMD) or liquid crystal devices (LCD). LEDs can be used in such devices. However, the adaption of the light distribution is done by the DMD or LCD system. Due to indirect switching, the amount of pixels can be increased to one million. However, such a system can have stringent requirements on the control system and the computer performance and its realization can be challenging and expensive.

### SUMMARY

Aspects and advantages of embodiments of the present disclosure will be set forth in part in the following description, or may be learned from the description, or may be learned through practice of the embodiments.

One example aspect of the present disclosure is directed to an LED module for use in automotive applications. The LED module can include a substrate. The LED module can include a plurality of chip-scale package LEDs. The plurality of chip-scale package LEDs can be arranged in a matrix on the substrate. Each chip-scale package LED can have a light emitting area that is about 80% or greater of a total area associated with the chip-scale package LED. Each chip-scale package LED can be separated from an adjacent chip-scale package LED by a gap. In some embodiments, a side coat material can be disposed in the gap.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a perspective view of an example LED module according to example embodiments of the present disclosure;

FIG. 2 depicts a top view of an example chip-scale package LED according to example embodiments of the present disclosure;

FIG. 3 depicts a cross-sectional view of an example LED module according to example embodiments of the present disclosure;

FIG. 4 depicts an example automotive system incorporating the LED module according to example embodiments of the present disclosure; and

FIG. 5 depicts a flow diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to an LED module. The LED module can be used, for instance, in automotive applications, such as in vehicle head lights and/or rear lights. The LED module can include a plurality of chip-scale package LEDs arranged in a matrix. The chip-scale package LEDs can be arranged so that there is a close distance between adjacent chip-scale package LEDs. For instance, in some embodiments, a distance between adjacent chip-scale package LEDs in the matrix can be less than about 500 μm, such as less than about 200 μm, such as in the range of about 30 μm to about 200 μm. As used herein, the use of the term “about” or “approximately” in conjunction with a numerical value or other metric is intended to refer to within 10% of the stated numerical value or metric.

By reducing the distance between adjacent chip-scale package LEDs in the matrix, a homogenous light distribution for the vehicle light can be obtained using a common, single primary optic in a vehicle lamp, such as a vehicle head light or vehicle rear light. In some implementations, a reflective material with low viscosity can be applied around one or more of the chip-scale package LEDs in the matrix as a side coat material to reduce optical cross-talk between the LEDs in the matrix and to increase reliability of the matrix (e.g., increase structural stability of the matrix).

In some embodiments, a reduced distance between light emitting areas of an LED matrix is achieved by using chip-scale package LEDs. Chip-scale package LEDs can have a light emitting area that is slightly smaller than or equal to the package size. For instance, the light emitting area can be about 80% or greater of the total package area associated with the chip-scale package LED, such as about 85% or greater of the total package area, such as about 90% or greater of the total package area, such as approximately equal to the total package area. In some embodiments, the size of the chip-scale package can be about 1.2 times greater or less than the size of the LED die.

The chip-scale package LEDs can emit light of any color or color temperature. In some embodiments, the chip-scale package LED can emit white light, in others orange or red light. In case of a white or orange (e.g., 580-620 nm) chip-scale package LED, the light emitting area can be the phosphor conversion layer and in case of a red chip-scale package LED (e.g., 620-780 nm), the light emitting area can be the phosphor conversion layer or the die itself.

In some embodiments, anode and cathode pads can be provided on the bottom of each chip-scale package LED. The chip-scale package can embody a flip-chip LED-die and can be applied without wires on a circuit board using, for instance, a surface mount technology (SMT)-based process with common die attach materials, such as conductive adhesives, soldering pastes, sintering pastes, transient liquid diffusion solders, etc. In some embodiments, an underfill material can be used in conjunction with mounting the chip-scale package LEDs to the substrate. In some embodiments, no underfill material is used.

A chip-scale package LED with a light emitting area equal to or nearly equal to the package size can radiate light under wide angles in an LED matrix, potentially leading to optical cross-talk of light from the light emitting areas of the LEDs. To reduce such optical cross-talk, an LED module can include a low-viscosity, high reflectivity side coat material applied around the chip-scale package LEDs in the matrix.

The side coat material can be, for instance, a low-viscosity material with high reflectance. The side coat material can reduce optical cross talk between adjacent chip-scale package LEDs. The side coat material can also provide increased mechanical stability for the LED module.

In some embodiments, the side coat material can be an epoxy resin. In some other embodiments, the side coat material can be a silicone-based material. In particular implementations, the side coat material can include a high filling of TiO₂ to cause the side coat material to have high reflectivity and a high dielectric constant.

In some embodiments, the side coat material can have a low viscosity. A low viscosity can include a viscosity that ranges between about 2500 mPas at 10 rpm and 25 ° C. to about 32000 mPas at 20 rpm and 25 ° C. measured with a cone-plate configuration (cone angle=3°, cone diameter=1.2 cm). In some embodiments, high reflectivity of the side coat material for wavelengths of light emitted from the chip scale package LEDs can be greater than 90% for all incident angles. Low transmissivity for wavelengths of light emitted from the chip-scale package LEDs can be less than 1%. In these cases, a low transmission value for the side coat material can determine the resolution and/or sharpness of dark-to bright transitions from a light distribution emanating from the LED module.

The side coat material can be heated such that it flows into the small gaps between adjacent chip-scale package LEDs. For instance, during application of the side coat material to the LED module, the side coat material can be heated so that the viscosity values drop to, for instance, less than about 500 mPas. In this way, the side coat material can be disposed in the gap using capillary effects. Due to capillary effects, the side coat material can be applied by flowing the side coat material into the gaps between adjacent chip-scale package LEDs in the LED matrix. The LED matrix can then be cured at a temperature between 100° C. and 200° C., such as between 140° C. to 160° C.

In some embodiments, the optical behaviors of the LED matrix can be tuned via selection of a side coat material with a desired refractive index. For instance, to keep the color shift as well as the loss of light due to absorption small, a side coat material with a high and constant refractive index in the visible range can be used. However, by an appropriate alteration of the refraction index of the side coat material, the color and/or color temperature of the radiated light can be modified according to specific requirements.

The side coat material can improve the mechanical stability and the reliability of LED module. In some embodiments, the side coat material can have a suitable coefficient of thermal expansion. As an example, for an epoxy resin side coat material, the coefficient of thermal expansion can be at about 13 ppm/K below T_{g} where T_{g} is a transition temperature associated with the epoxy resin. Silicone based side coat materials can have a high elastic modulus.

In some embodiments, the LED matrix can include various features for thermal management. For instance, the circuit board to which the chip-scale package LEDs are mounted can have a sufficient thermal conductivity. As an example, the circuit board can be an FR4 printed circuit board, a metal core printed circuit board (e.g., MC-PCB), isolated metal substrate, or ceramic substrate (e.g., aluminum nitride or aluminum oxide).

In some embodiments, the chip-scale package LEDs can be die attached to the circuit board. Die attach materials can include, for instance, solder pastes (e.g., SnAgCu and/or AuSn alloy), sinter pastes (e.g., Ag, Au, Cu), conductive adhesives (e.g., adhesives include high silver content), and/or other suitable die attach materials.

In some embodiments, thermal management for the LED matrix can be enhanced with a thermal pad located on a bottom side of the circuit board. The thermal pad can be in thermal communication with (e.g., mechanically coupled to) a heat sink and/or another circuit board.

The LED modules according to example embodiments of the present disclosure can provide a number of technical effects and benefits. For instance, the LED module can facilitate the use of a single primary optic to achieve a generally homogenous light distribution in automotive applications. A generally homogenous light distribution can be a distribution that is at least 80% uniform (less than 20% variance in intensity) over a distribution area for the application. The number and arrangement of chip-scale package LEDs in the matrix can be adapted to various requirements. Due to the tight packing of the chip-scale package LEDs in the matrix, the size and weight of the LED module can be reduced.

A goal of example aspects of the present disclosure is to create a LED-module comprising chip-scale package LEDs applied on a circuit board in a closely packed, matrix-like configuration which facilitates the use of a single primary optic to achieve a homogenous light distribution for automotive applications. This enables size and weight reduction as well as an easy adaption to customized matrix configurations of adaptive head lamps and rear lamps in vehicles.

One example aspect of the present disclosure is directed to a light emitting diode (LED) module. The LED module includes a substrate. The LED module includes a plurality of chip-scale package LEDs arranged in a matrix disposed on the substrate. Each chip-scale package LED has a light emitting area that is about 80% or greater of a total area associated with the package, such as about 85% or greater of a total area associated with the package, such as approximately equal to a total area associated with the package.

Each chip-scale package LED is separated from an adjacent chip-scale package LED by a gap. In some embodiments, the gap is substantially equal among adjacent LEDs in the module. In some embodiments, the gap has a distance of less than about 500 μm, such as less than about 200 μm, such as in the range of about 30 μm to about 200 μm.

In some embodiments, each chip-scale package LED has an anode and a cathode disposed on a bottom portion of the chip-scale package LED. The chip-scale package LED can be die attached to the substrate. In some embodiments, the LED module comprises a thermal pad disposed on a bottom surface of the substrate.

In some embodiments, the LED module includes a side coat material disposed within the gap. The side coat material can have a low viscosity. The side coat material can have a high reflectivity for wavelengths of light emitted by the plurality of chip-scale package LEDs. The side coat material can have a low transmissivity for wavelengths of light emitted by the plurality of chip-scale package LEDs. In some embodiments, a refractive index associated with the side coat material is selected to provide a desired color temperature output for the LED module

In some embodiments, the LED module can be implemented in a vehicle lamp. The vehicle lamp can be a head light or a rear light for an automotive vehicle. The LED module can be coupled to one or more control devices. The one or more control devices can be configured to individually control each chip-scale package LED in the LED module to provide a selected light output of the LED module.

Another example embodiment of the present disclosure is directed to a vehicle lamp. The vehicle lamp includes an LED module according to any aspects disclosed herein. The vehicle lamp can include a primary optic. The primary optic directs light emitted from the LED module as a generally homogenous light output from the vehicle lamp. In some embodiments, the primary optic directs light emitted from the LED module as a generally homogenous light output from the vehicle lamp without the use of a secondary optic.

Yet another example embodiment is directed to a process for manufacturing an LED module. The process includes placing a plurality of chip-scale package LEDs onto a substrate in a matrix such that each chip-scale package LED is separated from an adjacent chip-scale package LED by a gap. Each chip-scale package LED has a light emitting area that is about 80% or greater of a total area associated with the package. The process includes placing a side coat material into the gap. The process includes curing the LED module.

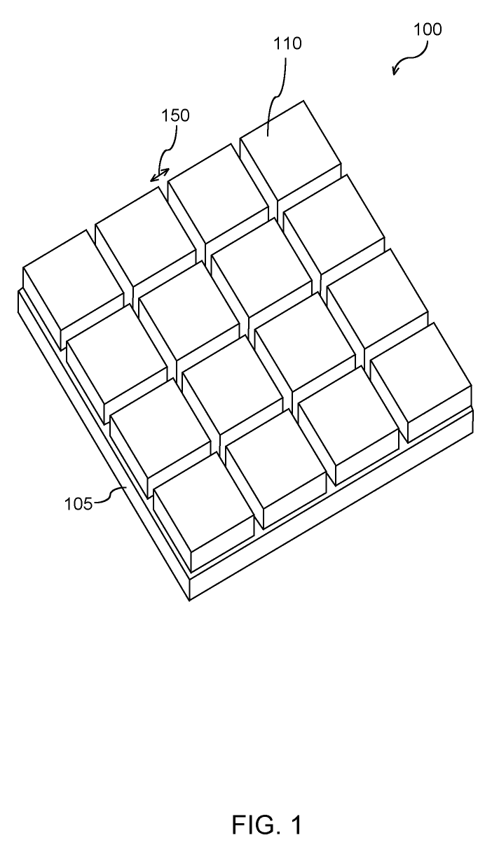

FIG. 1 depicts an example LED module 100 according to example aspects of the present disclosure. The LED module 100 can include a plurality of chip-scale package LEDs 110 arranged in a matrix on a substrate 105. The substrate 105 can be, for instance, an FR4 printed circuit board, a metal core printed circuit board (MC-PCB), isolated metal substrate, ceramic substrate (e.g., aluminum nitride or aluminum oxide), or other suitable substrate. In some embodiments, the LED module 100 includes at least 10 chip-scale package LEDs 110 arranged on a substrate.

A 4×4 matrix of chip-scale package LEDs 110 is illustrated in FIG. 1. However, those of ordinary skill in the art, using the disclosures provided herein, will understand that other suitable configurations of the module can be used without deviating from the scope of the present disclosure. As non-limiting examples, the module can be a 2×8 matrix, a 1×16 matrix, a 10×10 matrix, a 4×32 matrix, or other suitable arrangement of chip-scale package LEDs 110. In some embodiments, the module can have rows and/or columns of chip-scale package LEDs. Each row can have the same or different number of chip-scale package LEDs. Each column can have the same or different number of chip-scale package LEDs.

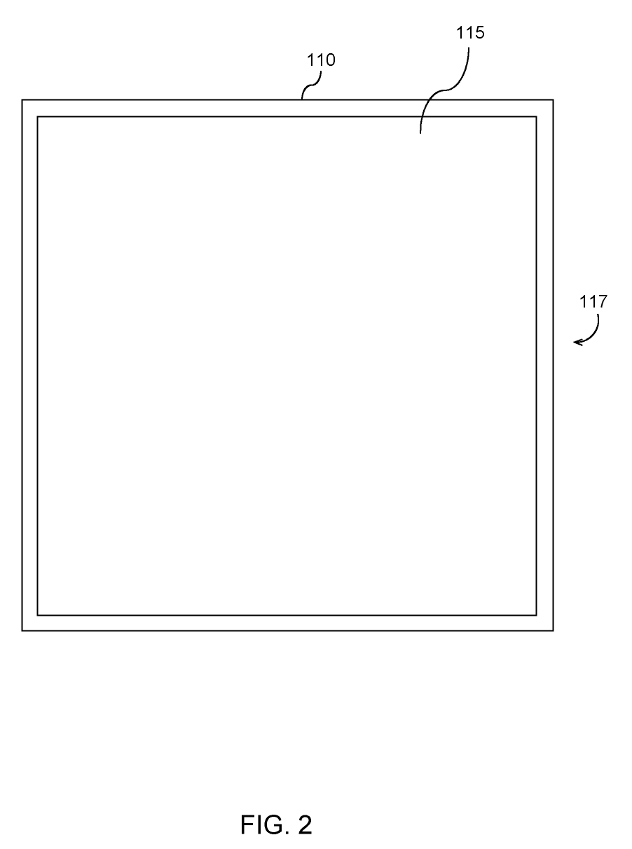

Each of the chip-scale package LEDs 110 can include a light emitting area that is slightly smaller than or equal to the package size. For instance, FIG. 2 depicts a top view of one example chip-scale package LED 110. As shown, the chip-scale package LED 110 has a light emitting area that emits light. The light emitting area 115 is nearly the same size as total package area 117 of the entire device 110. For instance, in some embodiments, the light emitting area 115 is about 80% or greater of the total package area 117 associated with the chip-scale package LED 110, such as about 85% or greater of the total package area 117, such as about 90% or greater of the total package area 117, such as approximately equal to the total package area 117.

Referring to FIG. 1, the plurality of chip-scale package LEDs 110 can be arranged such that there is a gap 150 between adjacent chip-scale package LEDs 110 in the matrix. The gap 150 can be such that there is close distance between adjacent chip-scale package LEDs 110. For instance, in some embodiments, the gap 150 can be associated with a distance of less than about 500 μm, such as less than about 200 μm, such as in the range of about 30 μm to about 200 μm. In example embodiments, the gap between adjacent LEDs can be substantially equal (e.g., within 15% of each other) throughout the module.

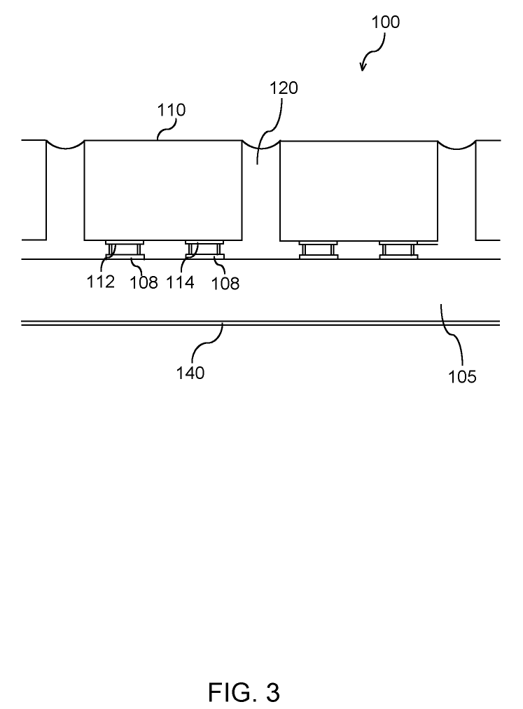

FIG. 3 depicts a cross-sectional view of a portion of an LED module 100 according to example aspects of the present disclosure. As shown, each chip-scale package LED 110 can include a cathode 112 and an anode 114 disposed on a bottom surface of the chip-scale package LED 110. The cathode 112 and anode 114 can be mounted via a conductor 108 to the substrate 105 using, for instance, surface mount technology.

In some embodiments, each chip-scale package LED 110 can be die attached to the substrate 105. Die attach materials can include, for instance, solder pastes (e.g., SnAgCu and/or AuSn alloy), sinter pastes (e.g., Ag, Au, Cu), conductive adhesives (e.g., adhesives include high silver content), and/or other suitable die attach materials.

As shown in FIG. 3, the LED module 100, in some example implementations, can include a thermal pad 140. The thermal pad 140 can be include thermally conductive material. The thermal pad 140 can be disposed on a bottom surface of the substrate 105 opposing the surface to which the chip-scale package LEDs 110 are mounted to the substrate 105. The thermal pad can be used to couple the substrate 105 to a heat sink and/or another substrate (e.g., circuit board).

Referring to FIG. 3, the LED module 100 can include a side coat material 120 disposed in the gaps 150 between adjacent chip-scale package LEDs 110. The side coat material 120 can be, for instance, a low-viscosity material with high reflectance. The side coat material can reduce optical cross talk between adjacent chip-scale package LEDs 110 in the module 100. The side coat material can also provide increased mechanical stability for the LED module 100.

In some embodiments, the side coat material 120 can be an epoxy resin. For an epoxy resin based side coat material 120, the coefficient of thermal expansion can be at about 13 ppm/K below T_{g} where T_{g} is a transition temperature associated with the epoxy resin.

In some embodiments, the side coat material 120 can be a silicone based material. The silicone based material can include a high filling of TiO₂ to cause the side coat material 120 to have high reflectivity and a high dielectric constant. Silicone based side coat material 120 can have a low elastic modulus.

In some embodiments, the side coat material 120 can have a viscosity that ranges between about 2500 mPas at 10 rpm and 25 ° C. to about 32000 mPas at 20 rpm and 25 ° C. measured with a cone-plate configuration (cone angle=3°, cone diameter=1.2 cm). During application of the side coat material to the LED module during manufacture, the side coat material can be heated so that the viscosity values drop towards values to less than about 500 mPas. In this way, the side coat material 120 can be disposed in the gap 150 using capillary effects.

In some embodiments, the reflectivity of the side coat material 120 for wavelengths of light emitted from the chip scale package LEDs 110 can be as high as possible for all incident angles (e.g., greater than about 90%). The transmission values (e.g., transmissivity) for wavelengths of light emitted from the chip-scale package LEDs 110 can be as low as possible (e.g., less than about 1%). A low transmission value for the side coat material can determine the resolution and/or sharpness of dark-to bright transitions from a light distribution emanating from the LED module 100.

In some embodiments, the optical behaviors of the LED matrix 100 can be tuned via selection of a side coat material 120 with a desired refractive index. For instance, to keep the color shift as well as the loss of light due to absorption small, a side coat material with a high and constant refractive index in the visible range can be used. However, by an appropriate alternation of the refraction index of the side coat material 120, the color of the radiated light can be modified according to specific requirements.

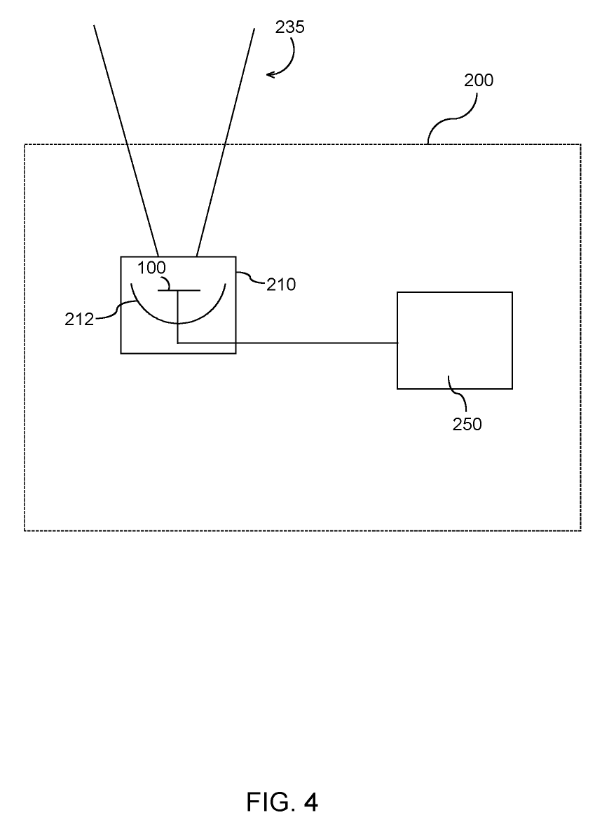

FIG. 4 depicts a block diagram of an example automotive system incorporating the LED module 100 according to example embodiments of the present disclosure. More specifically, the LED module 100 can be implemented as part of a vehicle lamp 210 (e.g., headlight, rear light, etc.) for a vehicle 200. The LED module 100 can have a plurality of chip-scale package LEDs arranged in a matrix as discussed with reference to FIGS. 1-3. The LED module 100 can be used in conjunction with a single primary optic 212 to provide a homogenous light output 235 from the vehicle lamp 210. The single primary optic 212 can direct light emitted from the LED module 100 as the light output 235 of the vehicle lamp 210.

The system can include one or more control devices 250 used to control the LED module 100 to provide a desired light output 235. For instance, the one or more control devices 250 can control the light output (e.g., brightness, on/off, etc.) of individual chip-scale package LEDs 110 in the module 100. The one or more control devices can include any suitable control devices and/or power conditioning circuits for controlling the chip-scale package LEDs.

As an example, the one or more control devices 250 can include driver circuit(s) for providing power to the individual chip-scale package LEDs. Power from the driver circuit(s) can be controlled (e.g., via one or more switching elements (e.g., transistors)) to control the output of the individual chip-scale package LEDs. In addition and/or in the alternative, the output of the driver circuit(s) can be controlled to control the light output from the individual chip-scale package LEDs.

The one or more control devices 250 can include one or more processors, microcontrollers, or other devices. In some embodiments, the one or more control devices 250 can include one or more processors and one or more memory devices. The one or more processors can execute computer-readable instructions stored in the one or more memory devices to perform operations, such as control of the individual chip-scale package LEDs in the module 100 to provide a desired light output 235 for the vehicle 200 (e.g., low beam, high beam, running lights, etc.).

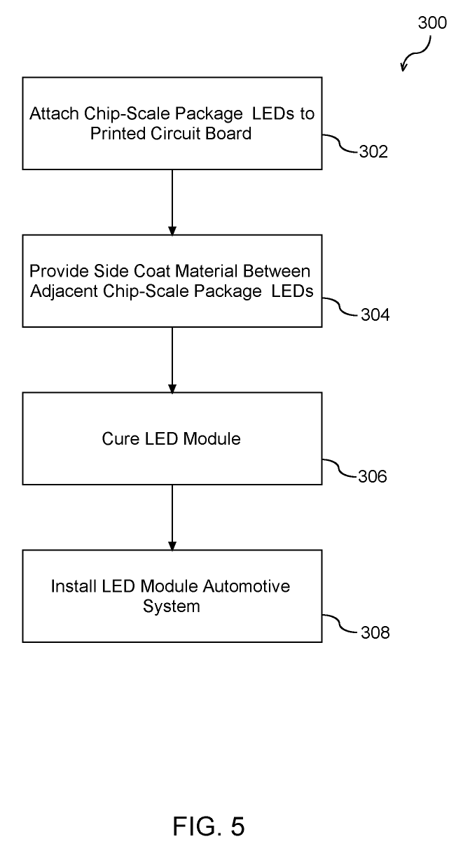

FIG. 5 depicts a flow diagram of an example method (300) for manufacturing an LED module according to example embodiments of the present disclosure. FIG. 5 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (502), the method can include attaching a plurality of chip-scale package LEDs to a substrate, such as a printed circuit board. The chip-scale package LEDs can be attached to the printed circuit board such the plurality of chip-scale package LEDs are arranged in a matrix. The chip-scale package LEDs can have an anode and a cathode located on a bottom surface of the chip-scale package LEDs. The anode and cathode can be coupled to the substrate using, for instance, SMT based processes.

In some embodiment, the chip-scale package LEDs can be die attached to the substrate. Die attach materials can include, for instance, solder pastes (e.g., SnAgCu and/or AuSn alloy), sinter pastes (e.g., Ag, Au, Cu), conductive adhesives (e.g., adhesives include high silver content), and/or other suitable die attach materials.

At (304), the method can include providing a side coat material between adjacent chip-scale package LEDs, such as in gaps formed between adjacent chip-scale package LEDs in the matrix. As discussed above, the side coat material can be, for instance, a low-viscosity material with high reflectance. The side coat material can reduce optical cross talk between adjacent chip-scale package LEDs. The side coat material can also provide increased mechanical stability for the LED module.

In some embodiments, the side coat material can be an epoxy resin. For an epoxy resin based side coat material, the coefficient of thermal expansion can be at about 13 ppm/K below T_{g} where T_{g} is a transition temperature associated with the epoxy resin. In some embodiments, the side coat material 120 can be a silicone based material. The silicone based material can include a high filling of TiO₂ to cause the side coat material to have high reflectivity and a high dielectric constant. A silicone based side coat material can have a high elastic modulus.

In some embodiments, the side coat material can have a viscosity that ranges between about 2500 mPas at 10 rpm and 25 ° C. to about 32000 mPas at 20 rpm and 25 ° C. The reflectivity of the side coat material for wavelengths of light emitted from the chip scale package LEDs can be as high as possible for all incident angles (e.g., greater than about 90%). The transmission values for wavelengths of light emitted from the chip-scale package LEDs can be as low as possible (e.g., less than about 1%). A low transmission value for the side coat material can determine the resolution and/or sharpness of dark-to bright transitions from a light distribution emanating from the LED module.

The side coat material can be heated such that it flows into the small gaps between adjacent chip-scale package LEDs. For instance, during application of the side coat material to the LED module, the side coat material can be heated so that the viscosity values drop towards values to less than about 500 mPas. In this way, the side coat material can be disposed in the gap using capillary effects.

At (306), the method can include curing the LED module. For instance, once the side coat material is disposed in the gaps between adjacent chip-scale package LEDs, the LED module can be heated during a curing process. The curing process can heat the LED module to a temperature in the range of about between 100° C. and 200° C., such as between 140° C. to 160° C.

At (308), the method can include installing the LED module into an automotive system, such as into a vehicle lamp. The vehicle lamp can be, for instance, a vehicle head light or a vehicle rear light. The vehicle lamp can include a single primary optic for providing homogenous light from the LED module. In some embodiments, the individual chip-scale package LEDs in the LED module can be controlled to provide desired light output (e.g., low beam, high beam, daytime running light) using the LED module.

Aspects of the present disclosure are discussed with reference to an LED module for use in automotive applications. Those of ordinary skill in the art, using the disclosures provided herein, will understand that the LED module can be used in other applications without deviating from the scope of the present disclosure.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A light emitting diode (LED) module, comprising:
a substrate; and
a plurality of chip-scale package LEDs arranged in a matrix disposed on the substrate, wherein each chip-scale package LED has a light emitting area that is about 80% or greater of a total area associated with the chip-scale package LED;
wherein each chip-scale package LED is separated from an adjacent chip-scale package LED by a gap.

2. The LED module of claim 1, wherein the gap has a distance of less than about 500 μm.

3. The LED module of claim 1, wherein the gap has a distance of less than about 200 μm.

4. The LED module of claim 1, wherein the gap has a distance in the range of about 30 μm to about 200 μm.

5. The LED module of claim 1, wherein each chip-scale package LED has a light emitting area that is about 85% or greater of a total area associated with the chip-scale package LED.

6. The LED module of claim 1 wherein each chip-scale package LED has a light emitting area that is approximately equal to the total area associated with the chip-scale package LED.

7. The LED module of claim 1, wherein each chip-scale package LED has an anode and a cathode disposed on a bottom portion of the chip-scale package LED.

8. The LED module of claim 7, wherein the chip-scale package LED is die attached to the substrate.

9. The LED module of claim 1, wherein the LED module comprises a side coat material disposed within the gap.

10. The LED module of claim 9, wherein the side coat material has low viscosity.

11. The LED module of claim 9, wherein the side coat material has high reflectivity for wavelengths of light emitted by the plurality of chip-scale package LEDs.

12. The LED module of claim 9, wherein the side coat material has low transmissivity for wavelengths of light emitted by the plurality of chip-scale package LEDs.

13. The LED module of claim 9, wherein a refractive index associated with the side coat material is constant for the visible range of light.

14. The LED module of claim 1, wherein the LED module comprises a thermal pad disposed on a bottom surface of the substrate.

15. The LED module of claim 1, wherein the LED module is implemented in a vehicle lamp.

16. The LED module of claim 1, wherein the vehicle lamp is a head light or a rear light for an automotive vehicle.

17. The LED module of claim 1, wherein the LED module is coupled to one or more control devices, the one or more control devices configured to individually control each chip-scale package LED in the LED module to provide a selected light output of the LED module.

18. A vehicle lamp comprising:
an LED module, the LED module comprising a substrate and a plurality of chip-scale package LEDs arranged in a matrix disposed on the substrate, wherein each chip-scale package LED has a light emitting area that is about 80% or greater of a total area associated with the chip-scale package LED, wherein each chip-scale package LED is separated from an adjacent chip-scale package LED by a gap; and
a primary optic;
wherein the primary optic directs light emitted from the LED module as a generally homogenous light output from the vehicle lamp.

19. The vehicle lamp of claim 18, wherein the primary optic directs light emitted from the LED module as a generally homogenous light output from the vehicle lamp without the use of a secondary optic.

20. A process for manufacturing an LED module, comprising:
placing a plurality of chip-scale package LEDs onto a substrate in a matrix such that each chip-scale package LED is separated from an adjacent chip-scale package LED by a gap, each chip-scale package LED has a light emitting area that is about 80% or greater of a total area associated with the package;
placing a side coat material into the gap; and
curing the LED module.
